(19) United States
(12) Patent Application Publication
(10) Pub. No.: US 2026/0326982 A1
(43) Pub. Date: Oct. 22, 2026

(54) CLIP FOR PELLICLE STORAGE CONTAINER, PELLICLE CASING, AND PELLICLE

(71) Applicant: MITSUI CHEMICALS, INC., Chuo-ku, Tokyo (JP)

(72) Inventors: Shu NISHIGOCHI, Chuo-ku, Tokyo (JP); Daiki TANEICHI, Chuo-ku, Tokyo (JP); Ken ITO, Chuo-ku, Tokyo (JP)

(73) Assignee: MITSUI CHEMICALS, INC., Chuo-ku, Tokyo (JP)

(21) Appl. No.: 19/491,026

(22) PCT Filed: May 15, 2024
(86) PCT No.: PCT/JP2024/018053

§ 371 Date: Dec. 8, 2025

(30) Foreign Application Priority Data
Jun. 9, 2023 (JP) 2023-095898

(51) Int. Cl. B65D 45/16; B65D 85/38; G03F 1/66

(52) U.S. Cl. CPC B65D 45/16; B65D 85/38; G03F 1/66

(57) ABSTRACT

There are provided a clip for a pellicle storage container, a pellicle casing, and a pellicle, in which an outgas amount of an organic substance gas having 20 or less carbon atoms evaluated under the following Condition 1 is 150 μg or less per 1 g of the clip:
Condition 1:
1 g of a cut piece of a clip is placed as a sample in a container, and an extract is obtained by Soxhlet extraction using 200 ml of hexane as an extraction solvent in a water bath at 80 °C for six hours, and the obtained extract is analyzed using gas chromatography, wherein, in the gas chromatography, a flame ionization detector is used as a detector, an amount of a component having 20 or less carbon atoms is detected, and a total amount of the detected component having 20 or less carbon atoms is defined as the outgas amount.

### TECHNICAL FIELD

The present disclosure relates to a clip for a pellicle storage container, a pellicle casing, and a pellicle.

### BACKGROUND ART

In a technology (photolithography) in which a photosensitive substance is applied to a surface of an object such as an electronic component, a printed circuit board, or a display panel and exposed in a pattern shape such that a pattern is formed, a transparent substrate called a mask in which a pattern is formed in one surface is used. In these manufacturing steps, patterning is performed by irradiating a photosensitive layer or the like with light through a mask (also referred to as an exposure original plate or a reticle). At this time, if foreign matter is adhered to the mask, light is absorbed in the foreign matter, or light is reflected and refracted from the surface of the foreign matter. As a result, a problem arises in that a formed pattern is deformed or an uneven edge is formed, and a dimension, quality, an appearance, or the like after patterning is impaired. In order to solve such a problem, a method is adopted in which a pellicle including a pellicle membrane that transmits light is attached to a surface of a mask to reduce adhesion of foreign matter.

In recent years, with the improvement in the performance of electronic components and the miniaturization of the line width, pellicles are also more likely to be affected by a trace amount of an outgas and fine particles than before.

In order to prevent foreign matter from being adhered to a pellicle during transportation, the pellicle may be packed in an order of a polycarbonate case with an opening portion clipped, an inner bag, a fastener bag, and an outer bag.

As an example of a storage container of a pellicle, a storage container using a urethane elastomer clip for closing a tray and a cover of the storage container is proposed as a pellicle storage container that reduces generation of abrasion powder produced due to friction in a case in which the pellicle is disposed and transported in the storage container (Japanese Patent Application Laid-Open (JP-A) No. 2007-128030).

### SUMMARY OF INVENTION

### Technical Problem

As a result of intensive studies, the present inventors have newly found that an outgas of a volatile organic component generated from a clip used in a packaging body that packages a pellicle is adhered to the packaged pellicle, and the outgas due to the clip becomes one of factors of pellicle contamination, in addition to an outgas of a volatile component derived from a material itself of the pellicle.

An object of an embodiment of the disclosure is to provide a clip for a pellicle storage container in which outgassing of a volatile organic component is reduced.

An object of another embodiment of the disclosure is to provide a pellicle casing which uses the clip for a pellicle storage container and in which generation of an outgas of a volatile organic component is reduced, and a pellicle in which an outgas amount due to adhesion of the outgas of the volatile organic component is reduced.

### Solution to Problem

Specific means for solving the above problem include the following aspects.

<1> A clip for a pellicle storage container, in which an outgas amount of an organic substance gas having 20 or less carbon atoms evaluated under the following Condition 1 is 150 μg or less per 1 g of the clip:
Condition 1:
1 g of a cut piece of a clip is placed as a sample in a container, and an extract is obtained by Soxhlet extraction using 200 ml of hexane as an extraction solvent in a water bath at 80 °C for six hours, and the obtained extract is analyzed using gas chromatography, in which, in the gas chromatography, a flame ionization detector is used as a detector, an amount of a component having 20 or less carbon atoms is detected, and a total amount of the detected component having 20 or less carbon atoms is defined as the outgas amount.

<2> A clip for a pellicle storage container, in which an outgas amount generated from one clip evaluated under the following Condition 2 is 2.000 μg or less:
Condition 2:
a clip is placed as a sample in a container and heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the clip is measured under a heating condition of 280 °C for ten minutes,
in which the total amount of the outgas is obtained by n-decane conversion, and the obtained total amount is divided by a number of clips serving as samples to obtain the outgas amount per clip.

<3> The clip for a pellicle storage container according to <1> or <2> contains at least one type of resin selected from the group consisting of a urethane resin, a polyethylene resin, a polyethylene terephthalate resin, a polyvinyl chloride resin, a polyamide resin, a polycarbonate resin, an acrylic resin, a methacrylic resin, and a phenol resin.

<4> A pellicle casing including: a pellicle; a pellicle storage container that stores the pellicle; the clip for a pellicle storage container according to any one of <1> to <3>, which fixes the pellicle storage container from an outer side; and a pellicle packaging body that packages the pellicle storage container.

<5> The pellicle casing according to <4>, in which the clip for a pellicle storage container that fixes the pellicle storage container from the outer side has a total amount of 1500 μg or less of an outgas amount of an organic substance gas having 20 or less carbon atoms measured under the following Condition 3:
Condition 3:
a clip used in a pellicle casing is placed as a sample in a container, and an extract is obtained by Soxhlet extraction using 200 ml of hexane as an extraction solvent in a water bath at 80 °C for six hours, and the obtained extract is analyzed using gas chromatography, in which, in the gas chromatography, a flame ionization detector is used as a detector, an amount of a component having 20 or less carbon atoms is detected, and a total amount of the detected component having 20 or less carbon atoms is defined as the outgas amount.

In a case in which the cut piece obtained by cutting a part of the clip is evaluated as the sample in Condition 3 described above, the total amount of the outgas may be obtained by the following Formula I.

[(Outgas Amount from Subject)×(Mass of Clip)]/(Mass of Subject)=Total Amount of Outgas Amount Formula I

<6> A pellicle including: a pellicle membrane; an adhesive for an original plate; and a pellicle frame, in which an outgas amount is 2.9 μg or less when measured under the following Condition 4:
Condition 4:
a pellicle is heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the pellicle is measured under a heating condition of 280 °C for ten minutes.

Here the total amount of the outgas is obtained by n-decane conversion.

<7> A pellicle casing including a pellicle storage container that stores a pellicle, the clip for a pellicle storage container according to any one of <1> to <3>, which fixes the pellicle storage container from an outer side, and a pellicle packaging body that packages the pellicle storage container, in which the pellicle, which is placed within the pellicle storage container, including: a pellicle membrane; an adhesive for an original plate; and a pellicle frame, in which an outgas amount is 2.9 μg or less when measured under the following Condition 4:
Condition 4:
a pellicle is heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the pellicle is measured under a heating condition of 280 °C for ten minutes.

Here the total amount of the outgas is obtained by n-decane conversion.

<8> The pellicle according to <6> or <7>, in which the adhesive for an original plate is a styrene butadiene-based adhesive.

### Advantageous Effects of Invention

According to an embodiment of the disclosure, it is possible to provide a clip for a pellicle storage container in which outgassing of a volatile organic component is reduced.

According to another embodiment of the disclosure, it is possible to provide a pellicle casing which uses the clip for a pellicle storage container and in which generation of an outgas of a volatile organic component is reduced, and a pellicle in which an outgas amount due to adhesion of the outgas of the volatile organic component is reduced.

### BRIEF DESCRIPTION OF DRAWINGS

FIG. 1 is a plan view showing an example of a clip for a pellicle storage container.

FIG. 2A is a side view of the clip for a pellicle storage container from one opening portion side.

FIG. 2B is a side view of the clip for a pellicle storage container from the other opening portion.

FIG. 3 is a perspective view showing an example of a pellicle storage container having four corners sealed by the clip for a pellicle storage container shown in FIG. 1.

FIG. 4 is a schematic cross-sectional view showing an example of a pellicle.

### DESCRIPTION OF EMBODIMENTS

In the disclosure, a numerical range indicated using “to” means a range including numerical values written before and after “to” as a minimum value and a maximum value, respectively.

In numerical ranges listed in stages in the disclosure, an upper limit value or a lower limit value written in a certain numerical range may be replaced with an upper limit value or a lower limit value of one of other numerical ranges listed in stages. In a numerical range described in the disclosure, an upper limit value or a lower limit value written in a certain numerical range may be replaced with a value shown in Examples.

In the disclosure, any combination of two or more preferred aspects is a more preferred aspect.

In the disclosure, in a case in which a plurality of kinds of substances corresponding to each component are described, the amount of each component means a total amount of the plurality of kinds of substances unless otherwise specified.

In the present specification, the term “step” includes not only an independent step but also a step that cannot be clearly distinguished from other steps as long as the intended purpose of the step is achieved.

### <Clip for Pellicle Storage Container 1>

A first aspect of a clip for a pellicle storage container of the disclosure is a clip for a pellicle storage container, in which an outgas amount of an organic substance gas having 20 or less carbon atoms evaluated under the following Condition 1 is 150 μg or less per 1 g of the clip.

In the disclosure, unless otherwise specified, the term “clip” indicates “a clip for a pellicle storage container”.

### Condition 1

1 g of a cut piece of a clip is placed as a sample in a container, and an extract is obtained by Soxhlet extraction using 200 ml of hexane as an extraction solvent in a water bath at 80 °C for six hours, and the obtained extract is analyzed using gas chromatography, wherein, in the gas chromatography, a flame ionization detector is used as a detector, an amount of a component having 20 or less carbon atoms is detected, and a total amount of the detected component having 20 or less carbon atoms is defined as the outgas amount.

In Condition 1, a component of the organic substance gas (hereinafter, also referred to as a specific organic substance gas) having 20 or less carbon atoms is derived from a calibration curve obtained from gas chromatography GC-FID obtained when a peak position of the corresponding number of carbon atoms is identified in gas chromatography by using an n-paraffin mixture standard fluid and a standard solution of n-C₂₀H₄₂ having a known concentration is measured.

In Condition 1, samples may be collected from a plurality of different clips, and an average value of measured values thereof may be taken, in consideration of variations in a generation amount of an outgas between the clips from which the samples are collected. In the case in which the samples are collected from the plurality of different clips and the average value of the measured values is taken, it is preferable to take an average value by collecting cut pieces as the samples from at least four clips, and it is more preferable to take an average value of eight clips, from the viewpoint of accuracy of the generation amount of an outgas.

In the first aspect of the clip of the disclosure, an outgas amount of a specific organic substance gas is 150 μg or less per 1 g of the clip, and from the viewpoint of reduction in outgas generation from the pellicle itself, the amount is preferably 100 μg or less per 1 g of the clip, more preferably 50 μg or less per 1 g of the clip, still more preferably 40 μg or less per 1 g of the clip, particularly preferably 30 μg or less per 1 g of the clip, and most preferably a detection limit or less or 0 μg.

Examples of the specific organic substance gas include a hydrocarbon compound having 20 or less carbon atoms selected from an aliphatic hydrocarbon compound and an aromatic hydrocarbon compound.

The outgas means a gas generated from a material as a component of the clip containing a resin or the like.

In consideration of an outgas amount in an entire pellicle casing, an outgas amount of a specific organic substance gas is preferably 405 μg or less per clip, more preferably 162 μg or less, still more preferably 135 μg or less, and particularly preferably 60 μg or less.

This is because it is usually preferable that a mass of a resin clip used for sealing the pellicle storage container is within a range of from 2 g to 5 g per clip. The mass of a general-purpose clip is about 2.7 g.

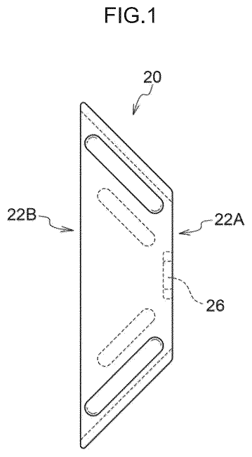

A shape of the clip is not particularly limited, and a clip having a known sealing mechanism can be selected and applied, if appropriate, as long as the pellicle storage container can be sealed. Examples of the clip include a fastener having a shape as shown in FIG. 1.

FIG. 1 is a plan view showing an example of the clip.

A clip 20 shown in FIG. 1 is made of a resin and has a trapezoidal shape in plan view as shown in FIG. 1, and compared with one opening portion 22A in a side surface, the other opening portion 22B is wider.

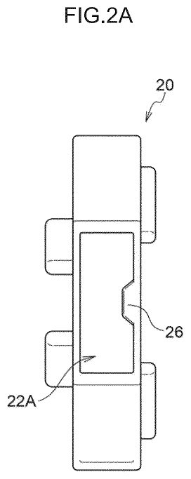

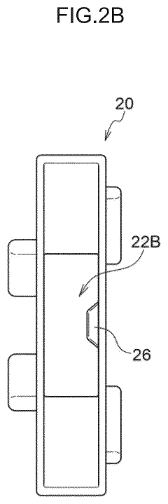

FIG. 2A is a side view of the clip 20 from the one opening portion side, and FIG. 2B is a side view of the clip 20 from the other opening portion side.

As shown in the side views of FIGS. 2A and 2B, the clip 20 may have a shape having a projecting portion 26 fitted into a recess (not shown) provided in a bottom portion of a pellicle storage container 24.

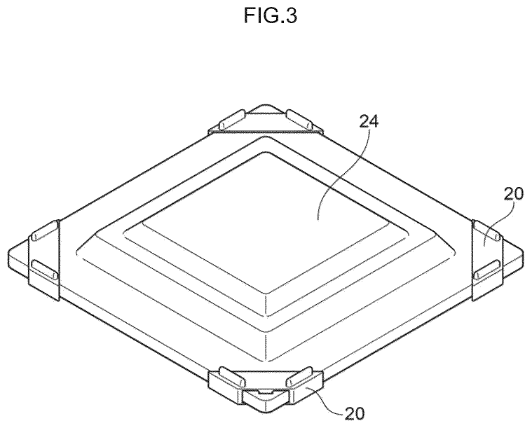

FIG. 3 is a perspective view showing an example of a state in which the clip 20 shown in FIG. 1 is attached to four corners of the pellicle storage container 24 from an outer side thereof. FIG. 3 shows an example in which the pellicle storage container 24 having a rectangular shape in plan view is used. The pellicle storage container 24 illustrated in FIG. 3 includes a main body and a lid portion.

The clip 20 shown in FIG. 1 is put on each angular portion of the four corners of the pellicle storage container 24 from the side of the wider opening portion 22B (the other opening portion) of the clips 20, whereby the main body and the lid portion of the pellicle storage container 24 can be fixed.

As shown in FIG. 3, the four corners of the pellicle storage container 24 having a rectangular shape in plan view are fixed by the clips 20 from the outer side of the pellicle storage container 24, whereby the projecting portions 26 of the clips 20 are fitted into the recess portions provided in the bottom portion of the pellicle storage container 24. In addition, the main body and the lid portion of the pellicle storage container 24 are fixed at the four corners, whereby the pellicle storage container 24 can be sealed, that is, fixed, by the four clips 20 from the outer side.

### <Clip for Pellicle Storage Container 2>

A second aspect of the clip for a pellicle storage container of the disclosure is a clip for a pellicle storage container, in which an outgas amount generated from one clip evaluated under the following Condition 2 is 2.000 μg or less.

### Condition 2

a clip is placed as a sample in a container and heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the clip is measured under a heating condition of 280 °C for ten minutes.

Here the total amount of the outgas is obtained by n-decane conversion, and the obtained total amount is divided by a number of clips serving as samples to obtain the outgas amount per clip.

Measurement conditions of the GCMS applied to the disclosure are as follows.
Measurement Device Name: GCMS-QP2010plus (Shimadzu Corporation)
Column: DB-1 (Inner Diameter: 0.32 mm, Length: 60 m, Thickness: 1.00 μm)
Scan Range: 35 m/Z to 450 m/Z
Ionization: 0.78 kV
Measurement Method: Calculate a gas amount generated at 280 °C for five minutes by n-decane conversion.

In Condition 2, it is preferable to collect samples from a plurality of different clips and to take an average value of measured values thereof, in consideration of variations in a generation amount of an outgas between the clips from which the samples are collected. In Condition 2, it is preferable to employ an average value by collecting cut pieces as the samples from at least four clips, and it is more preferable to employ an average value of eight clips, from the viewpoint of accuracy of the generation amount of an outgas.

In the disclosure, unless otherwise specified, an average value of eight clips is employed as the total amount of the specific organic substance gas.

In the second aspect of the clip of the disclosure, an outgas amount of a volatile organic component generated from the clips is 2.000 μg or less per clip, and from the viewpoint of reduction in outgas generation from the pellicle itself, the outgas amount is preferably 0.5 μg or less per clip, more preferably 0.05 μg or less per clip, still more preferably 0.04 μg or less per clip, particularly preferably 0.03 μg or less per clip, and most preferably a detection limit or less or 0 μg.

Here, the volatile organic component refers to an organic component that is volatilized under a condition of 25 °C and 1 atm.

Examples of the volatile organic component include a hydrocarbon compound such as an aromatic hydrocarbon compound or an aliphatic hydrocarbon compound.

As the clip of the disclosure, from the viewpoint of the generation reduction effect of the outgas from the pellicle, it is preferable that the outgas amount of the specific organic substance gas measured under the above Condition 1 defined in the first aspect of the disclosure is 150 μg or less per 1 g of the clip, and the outgas amount of the volatile organic component measured under the above Condition 2 defined in the second aspect of the disclosure is 2.000 μg or less per clip.

The clip of the disclosure preferably contains a resin having durometer hardness of D55 to D69.

The durometer hardness can be measured using a type D durometer indenter in accordance with JIS K 7215-1986 “Testing Methods for Durometer Hardness of Plastics” specified in Japanese Industrial Standards (JIS).

When durometer hardness of the resin contained in the clip is D55 or higher, generation of dust due to rubbing against a front surface of the clip is effectively reduced at a contact portion between the clip and the pellicle storage container. In addition, when the durometer hardness is D69 or lower, generation of dust due to rubbing against a surface of the pellicle storage container is effectively reduced at the contact portion between the clip and the pellicle storage container.

The durometer hardness of the resin contained in the clip is preferably in a range of from D55 to D69, and more preferably in a range of from D58 to D64.

The clip of the disclosure preferably contains at least one kind of resin selected from the group consisting of a urethane resin, a polyethylene resin, a polyethylene terephthalate resin, a polyvinyl chloride resin, a polyamide resin, a polycarbonate resin, an acrylic resin, a methacrylic resin, and a phenol resin.

Examples of the polyamide resin include PA6 and PA66.

In particular, the clip preferably contains at least one kind of resin selected from the group consisting of a polyethylene resin, a polypropylene resin, and a polyurethane resin from the viewpoint of the generation reduction effect of the outgas.

The clip may contain only one kind of resin or two or more kinds of resins.

From the viewpoint of outgas generation reduction from the clip itself, a heating treatment may be performed at a temperature equal to or lower than a softening point of the resin after the clip containing the resin is manufactured.

The clip containing the resin is heated at the softening point of the resin, for example, under a temperature condition of from 50 °C to 100 °C, preferably from 60 °C to 90 °C, for from about 10 hours to 30 hours, preferably from about 20 hours to 30 hours, whereby it is considered that a volatile component inherently contained in the resin contained in the clip is reduced, the outgas generation is more effectively reduced, and conditions of the outgas of the specific organic substance gas measured under Condition 1 and the outgas amount of the volatile organic component measured under Condition 2 are more likely to be achieved.

### <Pellicle Casing>

The pellicle casing of the disclosure includes the pellicle, the pellicle storage container that stores the pellicle, the clip for a pellicle storage container of the disclosure that fixes the pellicle storage container from the outer side, and a pellicle packaging body that packages the pellicle storage container.

According to the pellicle packaging body of the disclosure, the outgas amount from the pellicle due to adhesion of the outgas of the volatile organic component generated from the clip used in the pellicle casing is reduced.

The “pellicle casing” is used in a meaning of including pellicles and respective packaging members that package the pellicles.

In the pellicle casing of the disclosure, the pellicle is placed in the pellicle storage container made of a resin such as polycarbonate, for example, and the pellicle storage container is clipped at four corners, for example, and is unlikely to be affected by another packaging member. In addition, since the clip of the disclosure reduces the generation of the outgasses such as the specific organic substance gas and the volatile organic component that cause pellicle contamination in a low range, the outgas amount from the pellicle due to the adhesion of outgasses generated from the packaging members of the pellicle casing is further reduced.

When there is a pressure difference between an inside and an outside of the pellicle storage container at the time of opening the pellicle storage container, there is a possibility that the pressure difference leads to a trouble at the time of the opening such as difficulty in opening the pellicle storage container, and thus it is preferable that the inside of the pellicle storage container is not sealed.

The clip used in the pellicle casing of the disclosure preferably has a total amount of 648 μg or less of an outgas amount of an organic substance gas having 20 or less carbon atoms measured under the following Condition 3.

### Condition 3:

A clip used in a pellicle casing is placed as a sample in a container, and an extract is obtained by Soxhlet extraction using 200 ml of hexane as an extraction solvent in a water bath at 80 °C for six hours, and the obtained extract is analyzed using gas chromatography, in which, in the gas chromatography, a flame ionization detector is used as a detector, an amount of a component having 20 or less carbon atoms is detected, and a total amount of the detected component having 20 or less carbon atoms is defined as the outgas amount.

An evaluation method of Condition 3 is the same as a measurement method of Condition 1 described above except that the sample is changed from 1 g of the cut piece of the clip to the cut pieces of all the clips used in the pellicle casing.

In a case in which the cut piece obtained by cutting a part of the clip is evaluated as the sample in Condition 3 described above, the total amount of the outgas amount may be obtained by the following Formula I.

[(Outgas Amount from Subject)×(Mass of Clip)]/(Mass of Subject)=Total Amount of Outgas Amount Formula I

In the clip used in the pellicle casing of the disclosure, the total amount of the outgas amount of the organic substance gas having 20 or less carbon atoms measured under the above Condition 3 is preferably 1500 μg or less, more preferably 1000 μg or less, still more preferably 500 μg or less, particularly preferably 350 μg or less, and may be a measurement limit or less.

As the pellicle storage container, a known pellicle storage container can be applied.

Examples of a material of the pellicle storage container include a resin such as polycarbonate, a conductive material such as carbon nanotube, conductive carbon black, or inorganic particles.

As the pellicle used in the pellicle casing, a known pellicle can be applied. The pellicle includes, for example, a pellicle membrane and a support frame that supports the pellicle membrane.

A shape of the pellicle storage container is not particularly limited, and examples thereof include a box shape.

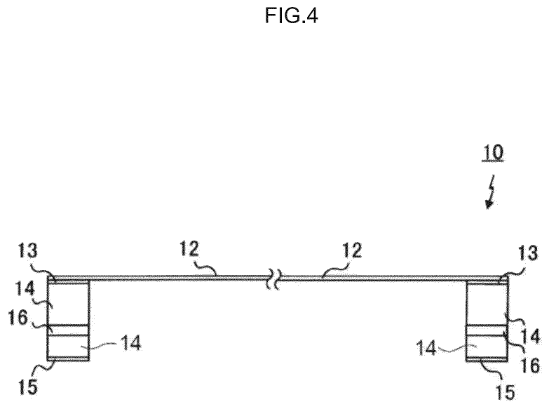

Hereinafter, one aspect of the pellicle will be described with reference to the drawing. FIG. 4 is a schematic cross-sectional view showing a pellicle 10. In the pellicle 10, a pellicle membrane 12 and a support frame 14 are bonded via an adhesive layer 13 for a membrane. In the support frame 14, a vent hole 16 is formed, and an adhesive layer 15 for an original plate is formed. Although not shown, a release sheet (for example, a separator) for protecting the adhesive layer 15 for an original plate may be further disposed on a surface of the adhesive layer 15 for an original plate. The support frame 14 need not have the vent hole 16, and the support frame 14 may have a structure in which a plurality of layers are layered. The pellicle membrane 12 is supported by the support frame 14.

Examples of a material of the pellicle membrane 12 include a transparent material such as quartz glass, a fluorine-based resin, cellulose acetate, or carbon nanotubes.

Examples of a material of the support frame 14 include an alumite treated aluminum frame, a titanium frame, and a silicon frame. The support frame 14 is preferably black from the viewpoint of preventing reflection of exposure light and facilitating inspection of presence of adhered foreign matter or the like.

With the adhesive layer 13 for a membrane, the support frame and the pellicle membrane adhere to each other.

A material of the adhesive layer 13 for a membrane is not particularly limited, and examples thereof include an acrylic resin adhesive, an epoxy resin adhesive, a silicone resin adhesive, or a fluoropolymer such as a fluorine-containing silicone adhesive.

In a case in which the pellicle membrane 12 and the support frame 14 can be brought into close contact with each other without interposing the adhesive layer 13 for a membrane therebetween, the adhesive layer 13 for a membrane need not be provided.

The adhesive layer 15 for an original plate can be formed by applying and drying a known adhesive, for example.

A material (hereinafter, also referred to as an adhesive for an original plate) of the adhesive layer 15 for an original plate is not particularly limited, and examples thereof include acryl-based, silicone-based, styrene-butadiene-based, urethane-based, and olefin-based adhesives.

The pellicle in the pellicle casing of the disclosure may contain an adhesive for an original plate, and the adhesive for an original plate may be the styrene butadiene-based adhesive.

The styrene butadiene-based adhesive is preferably used as a material of the adhesive layer 15 for an original plate with which the support frame 14 and the original plate adhere to each other in order to easily reduce distortion of the original plate.

The styrene butadiene-based adhesive is more likely to release outgas from the pellicle after the outgas of the volatile organic component generated from the pellicle packaging body has adhered to the pellicle. The pellicle packaging body according to the disclosure has the above-described configuration. Hence, even in a case in which the styrene butadiene-based adhesive is used as the material of the adhesive layer 15 for an original plate, the outgas amount from the pellicle due to adhesion of the outgas of the volatile organic component generated from the pellicle packaging body is reduced.

In the disclosure, the “adhesive” is a concept including an adhesive and a pressure-sensitive adhesive.

In the disclosure, the “adhesive layer” is a concept including an adhesive layer and a pressure-sensitive adhesive layer.

Examples of a material of the release sheet include a polyethylene terephthalate film and a polypropylene film.

As described above, depending on the materials of the pellicle membrane 12 and the support frame 14, the support frame and the pellicle membrane may adhere to each other without interposing the adhesive layer 13 for a membrane therebetween.

The pellicle of the disclosure has the pellicle membrane, the adhesive for an original plate, and the pellicle frame, and has an outgas amount of 2.9 μg or less when measured under the following Condition 4.

### Condition 4:

A pellicle is heated at 50 °C for four hours, and a generated outgas is adsorbed onto 150 mg of an adsorbent material, and thereafter, 150 mg of the adsorbent material is set in a gas chromatograph mass spectrometer (GCMS), and a total amount of an outgas of a volatile organic component generated from the pellicle is measured under a heating condition of 280 °C for ten minutes.

Here the total amount of the outgas is obtained by n-decane conversion.

A method for measuring the outgas of the volatile organic component in Condition 4 is the same as that in Condition 2 described above and uses the same measurement conditions of the GCMS to be applied except that the sample is changed from the clip to the pellicle.

The pellicle of the disclosure is placed in the pellicle storage container of the pellicle casing including the pellicle storage container that stores this pellicle, the clip for a pellicle storage container of the disclosure that fixes the pellicle storage container, and the pellicle packaging body that packages the pellicle storage container, the pellicle including a pellicle membrane, an adhesive for an original plate, and a pellicle frame. In addition, an outgas amount is 2.9 μg or less when measured under the following Condition 4.

### Condition 4:

A pellicle is heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the pellicle is measured under a heating condition of 280 °C for ten minutes.

Here the total amount of the outgas is obtained by n-decane conversion.

A method for measuring the outgas of the volatile organic component in the above Condition 4 is the same as that in Condition 2 described above and uses the same measurement conditions of the GCMS to be applied except that the sample is changed from the clip to the pellicle.

As the pellicle packaging body that packages the pellicle storage container, a known pellicle packaging body can be used. For example, the pellicle packaging body may be a layered body including at least two layers of a sealant layer and a base material layer.

From the viewpoint of the strength in use, the pellicle packaging body has the breaking strength of preferably 5 N or more and 50 N or less, more preferably 7 N or more and 45 N or less, and still more preferably 10 N or more and 40 N or less.

The breaking strength is measured in accordance with JIS-K7127-5 (1999) ((corresponding to ISO527-3:1995)). Both ends of a test piece type 5 (a dumbbell shape having a total length of 115 mm, a width of 6 mm of a parallel portion, a distance of 25 mm between marked lines, and a width of 25 mm of a holding portion) of JIS-K7127 are pulled to measure the breaking strength.

A specific technique of setting the breaking strength within the above-described range is not particularly limited, and examples thereof include a method of adjusting a material and a thickness of the base material layer.

The pellicle packaging body preferably includes at least two layers of the sealant layer and the base material layer, and more preferably includes the sealant layer, an adhesive layer, and the base material layer in this order.

In a case in which the pellicle packaging body is a layered body including at least two layers of the sealant layer and the base material layer, or in a case in which the pellicle packaging body is a layered body including the sealant layer, the adhesive layer, and the base material layer in this order, the outermost surface on the pellicle side may be the sealant layer, and the outermost surface on the outer circumferential surface side may be the base material layer.

In a case in which the pellicle packaging body includes at least two layers of the sealant layer and the base material layer, or in a case in which the pellicle packaging body is a layered body including the sealant layer, the adhesive layer and the base material layer in this order, it is considered that an outgas of a volatile organic component in the pellicle packaging body is likely to be generated from the sealant layer. Therefore, when the outermost surface on the pellicle side is the sealant layer, adhesion of an outgas of a volatile organic component generated from the pellicle packaging body also becomes remarkable. On the contrary, the pellicle packaging body of the disclosure has the above-described configuration, whereby the outgas amount from the pellicle due to adhesion of the outgas of the volatile organic component generated from the pellicle packaging body is likely to be maintained to be small.

### (Sealant Layer)

The sealant layer may be a single layer or a layered body including two or more layers.

A material of the sealant layer is not particularly limited, and a composition containing a known resin can be applied thereto.

Examples of the resin include: a polyolefin resin which is a homopolymer such as polyethylene (PE) (including high-density polyethylene (HDPE), medium-density polyethylene (MDPE), low-density polyethylene (LDPE), linear low-density polyethylene (LLDPE), or the like), polypropylene (PP), polybutene, or polymethylpentene; two or more kinds of copolymers selected from the group consisting of olefins such as ethylene, propylene, butene, and methylpentene; a polyester resin such as polyethylene terephthalate (PET), polybutylene terephthalate (PBT), or polyethylene naphthalate; a polyamide resin such as nylon-6, nylon-6,6, metaxylenediamine-adipic acid condensation polymer, or polymethylmethacrylimide; or an ethylene-vinyl alcohol copolymer. A resin to be used in forming the sealant layer may be used singly or in combination of two or more kinds thereof.

Among the examples, the material of the sealant layer preferably contains at least one kind selected from the group consisting of a polyester resin, a polyamide resin, and an ethylene-vinyl alcohol copolymer, more preferably contains at least one kind selected from the group consisting of a polyester resin and an ethylene-vinyl alcohol copolymer, and still more preferably contains an ethylene-vinyl alcohol copolymer, from the viewpoint of further reducing the outgas amount from the pellicle due to adhesion of the outgas of the volatile organic component generated from the pellicle packaging body.

The sealant layer preferably has a thickness (a total thickness in the case of a layered structure including two or more layers) of 500 μm or less, more preferably 100 μm or less, still more preferably 50 μm or less, and particularly preferably 40 μm or less.

When the thickness of the sealant layer is less than or equal to the above-described range, the outgas amount from the pellicle due to adhesion of the outgas of the volatile organic component generated from the pellicle packaging body is further reduced.

The sealant layer may have a thickness (a total thickness in the case of a layered structure including two or more layers) of 3 μm or more, 5 μm or more, or 15 μm or more from the viewpoint of sealability.

From the above viewpoint, the sealant layer may have a thickness (a total thickness in the case of a layered structure including two or more layers) of from 3 μm to 500 μm, or from 3 μm to 40 μm.

As described above, in a case in which the pellicle packaging body includes at least two layers of the sealant layer and the base material layer, it is considered that an outgas of a volatile organic component in the pellicle packaging body is likely to be generated from the sealant layer. Therefore, as the thickness of the sealant layer increases, the outgas of the volatile organic component generated from the pellicle packaging body is likely to be remarkably adhered. On the contrary, the pellicle packaging body of the disclosure has the above-described configuration, whereby the outgas amount from the pellicle due to adhesion of the outgas of the volatile organic component generated from the pellicle packaging body is likely to be maintained to be small.

### (Base Material Layer)

The base material layer may be a single layer or a layered body including two or more layers.

A material of the base material layer is not particularly limited, and a composition containing a known resin can be applied thereto.

Examples of the resin include a polyolefin-based resin such as polyethylene (including high-density polyethylene (HDPE), medium-density polyethylene (MDPE), low-density polyethylene (LDPE), linear low-density polyethylene (LLDPE), or the like), an ethylene-propylene copolymer, an ethylene-butene copolymer, an ethylene-hexene copolymer, an ethylene-octene copolymer, polypropylene (PP), an ethylene-vinyl acetate copolymer, an ethylene-methyl methacrylate copolymer, or an ionomer resin; a polyester-based resin such as polyethylene terephthalate (PET), polybutylene terephthalate (PBT), or polyethylene naphthalate; an amide resin such as nylon-6, nylon-6,6, metaxylenediamine-adipic acid condensation polymer, or polymethylmethacrylimide; an acrylic resin such as polymethyl methacrylate; a styrene-acrylonitrile-based resin such as polystyrene, styrene-acrylonitrile copolymer, styrene-acrylonitrile-butadiene copolymer, or polyacrylonitrile; a hydrophobized cellulose resin such as cellulose triacetate or cellulose diacetate; a halogen-containing resin such as polyvinyl chloride, polyvinylidene chloride, polyvinylidene fluoride, or Teflon (registered trademark); a high hydrogen-bonding resin such as polyvinyl alcohol, an ethylene-vinyl alcohol copolymer, or a cellulose derivative; or an engineering plastic resin such as a polycarbonate resin, a polysulfone resin, a polyethersulfone resin, a polyetheretherketone resin, a polyphenylene oxide resin, a polymethylene oxide resin, and a liquid crystal resin. The resin may be used singly or in combination of two or more kinds thereof.

Among the above-mentioned examples, a material which is unlikely to generate static electricity (preferably an antistatic-treatment-treated resin, more preferably a resin containing any one of polyethylene terephthalate and polyethylene naphthalate) or the like is preferable as the material of the base material layer from the viewpoint of preventing dust or other debris from being adhered to the front surface of the pellicle packaging body.

A thickness of the base material layer (a total thickness in the case of a layered structure including two or more layers) is not particularly limited, and is, for example, preferably from 0.1 μm to 500 μm, more preferably from 1 μm to 100 μm, and still more preferably from 5 μm to 30 μm.

### (Adhesive Layer)

The pellicle packaging body of the disclosure may have an adhesive layer between the sealant layer and the base material layer, if necessary.

The adhesive layer may be a single layer or a layered body including two or more layers.

A material of the adhesive layer is not particularly limited, and a composition containing a known resin can be applied thereto.

Examples of the resin include a polyurethane resin, a polyester resin, a polyether resin, or a mixture thereof.

A thickness of the adhesive layer is not particularly limited and is preferably 1 μm or more, and more preferably 2 μm or more, for example, from the viewpoint of the adhesive strength.

The thickness of the adhesive layer is not particularly limited and is preferably 5 μm or less, and more preferably 4 μm or less, for example, from the viewpoint of shortening a curing reaction time during formation of the adhesive layer and from the viewpoint of reducing a percentage of an unreacted substance or a residual solvent during the curing reaction.

### (Shape and Properties of Pellicle Packaging Body)

A shape of the pellicle packaging body is not particularly limited.

Examples of the shape of the pellicle packaging body include a sheet shape, a bag shape, a pack shape, or a box shape.

The pellicle packaging body may include, in a part of the packaging body, if necessary, a packaging member in which a total amount of an outgas from the volatile organic component under a heating condition of 100 °C for 30 minutes exceeds 90 ppm as long as the effects of the disclosure can be obtained. A percentage of the packaging member in which the total amount of the outgas in the pellicle packaging body exceeds 90 ppm is preferably 20% by mass or less, more preferably 10% by mass or less, and still more preferably 5% by mass or less with respect to the entire pellicle packaging body. It is preferable that the pellicle packaging body does not include a packaging member having a total amount of the outgas exceeding 90 ppm.

A volume of the pellicle packaging body is not particularly limited and can be set depending on a size and a packaging shape of the pellicle, if appropriate. The volume of the packaging body is, for example, preferably 2000 cm³ to 70000 cm³, more preferably 4000 cm³ to 30000 cm³, and still more preferably 5000 cm³ to 10000 cm³.

When the volume of the pellicle packaging body is within the above range, balance between a volume of the pellicle or the pellicle storage container packaged in the pellicle packaging body and a surface area of the pellicle packaging body is easily optimized. Therefore, a percentage of the outgas of the volatile organic component generated from the pellicle packaging body is further reduced, and the outgas amount from the pellicle due to the adhesion of the outgas generated from the pellicle packaging body is further reduced.

### EXAMPLES

Hereinafter, the disclosure will be described in more detail according to examples or the like, but the invention of the disclosure is not limited only to these examples.

### Experimental Examples 1 to 3 and Comparative Examples 1 and 2

The pellicle casing was obtained using the clips shown in the table, and results of the total amount of the outgas from the volatile organic component of the clip and the pellicle packaged in the casing were measured.

### Example 1

(1) Preparation of Various Kinds of Components which are Raw Materials of Mask Adhesive

### Thermoplastic Elastomer (A)

Styrene-hydrogenated isoprene-styrene block copolymer (trade name: “Hibler 7125” (manufactured by Kuraray Co., Ltd.), tan 8 peak temperature: −5 °C, and styrene content percentage: 20% by mass)

### Tackifier Resin (B)

Hydrogenated alicyclic petroleum resin: C9 hydrogenated petroleum resin (trade name: “ARKON P-100” (manufactured by Arakawa Chemical Industries, Ltd.), softening point: 100±5 °C, number average molecular weight (Mn): 610) and rosin ester resin (trade name: PINECRYSTAL KE-311 (manufactured by Arakawa Chemical Industries, Ltd.), softening point: 100±5 °C)

### Softener

Polybutene (trade name: “Nissan Polybutene 30N” (manufactured by NOF CORPORATION))

### Wax

Polypropylene pyrolysis wax (trade name: “Hi-WAX NP055” (manufactured by Mitsui Chemicals, Inc.))

### (2) Manufacture of Pellicle

First, 100 parts by mass of the thermoplastic elastomer (A), 100 parts by mass of the tackifier resin (B), and 200 parts by mass of the softener were mixed so that a total amount of 48 g was obtained, and a raw material mixture was obtained. The obtained raw material mixture was put into Labo Plastomill (manufactured by Toyo Seiki Seisaku-sho, Ltd., internal capacity: 60 mL), and then sealed. The mixture was kneaded at 200 °C and 100 rpm (rotation/min) for 20 minutes to obtain a lumpy mask adhesive. About 10 g of the mask adhesive was put into a heating tank (a temperature in the tank: 200 °C) and melted. As shown in FIG. 4, the support frame 14 (an external dimension: 148.77 mm×114.9 mm, a frame height H: 2.5 mm, a frame width W: 2 mm) made of anodized aluminum was prepared. The melted mask adhesive extruded from a needle tip communicating with the heating tank was applied onto one end surface of the support frame 14 to form the adhesive layer 15 for an original plate. A thickness of the formed adhesive layer 15 for an original plate was 0.6 mm. A separator was disposed on a surface of the adhesive layer 15 for an original plate. The pellicle membrane 12 was attached onto the other end surface of the support frame 14 (that is, the end surface on a side on which the adhesive layer 15 for an original plate was not formed) via the adhesive layer 13 for a membrane (fluoropolymer (AGC Inc., CYTOP A type)) to obtain the pellicle 10.

### (3) Preparation of Pellicle Casing

The prepared pellicle was placed in a polycarbonate storage container.

Four polyethylene clips heat-treated at 90 °C for 24 Hr in the air atmosphere were prepared.

A mass of 2.9 g was measured per clip.

Four corners of the polycarbonate storage container were fixed by the prepared four clips. The polycarbonate storage container fixed by the clips was stored at 23 °C for two months in a state of being packaged in the pellicle packaging body.

The pellicle packaging body was a layered body having a base material: polyethylene terephthalate and a sealant layer: an ethylene-vinyl alcohol copolymer and had a thickness of 25 μm.

(1. Evaluation of Total Amount of Outgas from Clip)

Regarding the clips used in the pellicle casing, the total amount of the outgas was measured under the following Conditions 1 and 2.

The measurement was performed three times on different samples, and an average value thereof was shown in Table 1.

### —Condition 1—

1 g of a cut piece of the clip was placed as a sample in a container, and an extract was obtained by Soxhlet extraction using 200 ml of hexane as an extraction solvent in a water bath at 80 °C for six hours.

The obtained extract was analyzed using the gas chromatography. In the gas chromatography, the flame ionization detector was used as a detector, an amount of a component having 20 or less carbon atoms was detected, and a total amount of the detected component having 20 or less carbon atoms was defined as the outgas amount of the organic substance gas having 20 or less carbon atoms.

In Condition 1, the component of the organic substance gas having 20 or less carbon atoms was derived from a calibration curve obtained from gas chromatography GC-FID obtained when a peak position of the corresponding number of carbon atoms is identified in the gas chromatography by using an n-paraffin mixture standard fluid and a standard solution of n-C₂₀H₄₂ having a known concentration is measured.

### —Condition 2—

The clip was placed as the sample in the container and heated at 50 °C for four hours, and a generated outgas was adsorbed onto 150 mg of an adsorbent material. Thereafter, 150 mg of the adsorbent material was set in the gas chromatograph mass spectrometer (GCMS), and a total amount of an outgas of a volatile organic component generated from the clip was measured under a heating condition of 280 °C for ten minutes.

Here, the total amount of the outgas was obtained by n-decane conversion, and the obtained total amount was divided by the number of clips which was the samples to obtain the outgas amount per clip.

Measurement conditions of the GCMS applied to the disclosure are as follows.
Measurement Device Name: GCMS-QP2010plus (Shimadzu Corporation)
Column: DB-1 (Inner Diameter: 0.32 mm, Length: 60 m, Thickness: 1.00 μm)
Scan Range: 35 m/Z to 450 m/Z
Ionization: 0.78 kV
Measurement Method: Calculate a gas amount generated at 280 °C for five minutes by n-decane conversion.
   (2. Evaluation of Total Amount of Outgas from Pellicle)

The pellicle stored in the pellicle casing was placed in a clean oven under the air atmosphere and heated in a range of from 70 °C to 80 °C for 20 hours to prepare a degassed pellicle.

The pellicle packaging body was used to package the pellicle, and the pellicle was stored at 23 °C for one week. After the storage, the pellicle was taken out from the pellicle packaging body and set in an oven. Then, the outgas generated under the heating condition of 50 °C for four hours was adsorbed onto Tenax (Trademark, manufactured by GL Sciences Inc.) which is the powdery adsorbent material. Thereafter, Tenax was set in the GCMS, and the total amount (μg) of the outgas of the volatile organic component generated from the pellicle was measured (by the n-decane conversion) under the heating conditions of 280 °C for ten minutes, and this total amount was set as the “total amount (μg/pellicle) of the outgas from the pellicle”.

The measurement was performed twice on individually different samples, and the average value thereof was shown in Table 1.

### Example 2

A clip and a pellicle casing were prepared in the same manner as in Example 1, except that the clip was prepared using the same polyethylene resin as in Example 1 and the heating condition was at 60 °C for 24 hours, and the evaluation was performed in the same manner as in Example 1. The results are shown in Table 1.

### Example 3

A clip and a pellicle casing were prepared and evaluated in the same manner as in Example 1 except that the clip was prepared using a polypropylene resin and the heating condition was at 90 °C for 24 hours. The results are shown in Table 1.

### Comparative Example 1

A clip and a pellicle casing were prepared in the same manner as in Example 1 except that the clip was prepared using the same polyethylene resin as in Example 1 and heating was not performed, and evaluation thereof was performed in the same manner as in Example 1. The results are shown in Table 1.

### Comparative Example 2

A clip and a pellicle casing were prepared in the same manner as in Example 2 except that the clip was prepared using the same polypropylene resin as in Example 2 and heating was not performed, and evaluation thereof was performed in the same manner as in Example 1. The results are shown in Table 1.

In the following Table 1, PE represents polyethylene, and PP represents polypropylene.

The durometer hardnesses of the resins contained in the clips of Examples 1 to 3 and Comparative Examples 1 and 2 measured in accordance with JIS K 7215-1986 were all within the range of from D55 to D69.

TABLE 1

| | | | Evaluation results | | | |
|---|---|---|---|---|---|---|
| | | | | Outgas amount of clip - | | |
| | Types of clips | | | Condition 2- | | Outgas |
| | | Treatment | Outgas amount of | | Total amount | amount of |
| | Resin | conditions | clip -Condition 1- | One clip | for eight clips | pellicle (μg) |
| Example 1 | PE | 90 °C 24 Hr | 29 μg/1 g of clip | 0.025 μg/1 pc | 0.2 μg/8 pcs | <0.1 |
| Example 2 | PE | 60 °C 24 Hr | 60 μg/1 g of clip | 0.063 μg/1 pc | 0.5 μg/8 pcs | 0.4 |
| Example 3 | PP | 90 °C 24 Hr | 45 μg/1 g of clip | 0.038 μg/1 pc | 0.3 μg/8 pcs | 0.1 |
| Comparative | PE | Non-heating | 190 μg/1 g of clip | 3.388 μg/1 pc | 27.1 μg/8 pcs | 3 |
| Example 1 | | | | | | |
| Comparative | PP | Non-heating | 210 μg/1 g of clip | 3.875 μg/1 pc | 31.0 μg/8 pcs | 3.5 |
| Example 2 | | | | | | |

As shown in Table 1, it was found that, in the clips of Examples 1 to 3 and the pellicles packaged in the pellicle packaging bodies by using the clips of Examples 1 to 3, the outgas amount from the pellicle due to the adhesion of the outgas of the volatile organic component generated was reduced as compared with the clips of Comparative Examples 1 and 2 and the pellicles packaged in the pellicle packaging bodies by using the clips of Comparative Examples 1 and 2.

### REFERENCE SIGNS LIST

10 Pellicle
12 Pellicle membrane
13 Adhesive layer for membrane
14 Support frame
15 Adhesive layer for original plate
16 Vent hole
20 Clip for pellicle storage container (clip)
22A One opening portion of clip (narrower opening portion)
22B The other opening portion of clip (wider opening portion)
24 Pellicle storage container
26 Projecting portion of clip

The disclosure of Japanese Patent Application No. 2023-95898 filed on Jun. 9, 2023 is incorporated herein by reference.

All of the literature, patent applications, and technical standards described in the disclosure are incorporated herein by reference to the same extent that individual literature, patent applications, and technical standards were specifically and individually indicated to be incorporated by reference.

1. A clip for a pellicle storage container, wherein an outgas amount of an organic substance gas having 20 or less carbon atoms evaluated under the following Condition 1 is 150 μg or less per 1 g of the clip:
Condition 1:
1 g of a cut piece of a clip is placed as a sample in a container, and an extract is obtained by Soxhlet extraction using 200 ml of hexane as an extraction solvent in a water bath at 80 °C for six hours, and the obtained extract is analyzed using gas chromatography,
wherein, in the gas chromatography, a flame ionization detector is used as a detector, an amount of a component having 20 or less carbon atoms is detected, and a total amount of the detected component having 20 or less carbon atoms is defined as the outgas amount.

2. A clip for a pellicle storage container, wherein an outgas amount generated from one clip evaluated under the following Condition 2 is 2.000 μg or less:
Condition 2:
a clip is placed as a sample in a container and heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the clip is measured under a heating condition of 280 °C for ten minutes,
wherein the total amount of the outgas is obtained by n-decane conversion, and the obtained total amount is divided by a number of clips serving as samples to obtain the outgas amount per clip.

3. The clip for a pellicle storage container according to claim 1, comprising at least one type of resin selected from the group consisting of a urethane resin, a polyethylene resin, a polyethylene terephthalate resin, a polyvinyl chloride resin, a polyamide resin, a polycarbonate resin, an acrylic resin, a methacrylic resin, and a phenol resin.

4. A pellicle casing comprising:
a pellicle;
a pellicle storage container that stores the pellicle;
the clip for a pellicle storage container according to claim 1, which fixes the pellicle storage container; and
a pellicle packaging body that packages the pellicle storage container.

5. The pellicle casing according to claim 4, wherein the clip for a pellicle storage container that fixes the pellicle storage container has a total amount of 1500 μg or less of an outgas amount of an organic substance gas having 20 or less carbon atoms measured under the following Condition 3:
Condition 3:
a clip used in a pellicle casing is placed as a sample in a container, and an extract is obtained by Soxhlet extraction using 200 ml of hexane as an extraction solvent in a water bath at 80 °C for six hours, and the obtained extract is analyzed using gas chromatography,
wherein, in the gas chromatography, a flame ionization detector is used as a detector, an amount of a component having 20 or less carbon atoms is detected, and a total amount of the detected component having 20 or less carbon atoms is defined as the outgas amount.

6. A pellicle comprising:
a pellicle membrane;
an adhesive for an original plate; and
a pellicle frame,
wherein an outgas amount is 2.9 μg or less when measured under the following Condition 4:
Condition 4:
a pellicle is heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the pellicle is measured under a heating condition of 280 °C for ten minutes,
wherein the total amount of the outgas is obtained by n-decane conversion.

7. A pellicle casing comprising:
a pellicle storage container that stores a pellicle,
the clip for a pellicle storage container according to claim 1, which fixes the pellicle storage container, and
a pellicle packaging body that packages the pellicle storage container,
wherein the pellicle, which is placed within the pellicle storage container, comprises:
a pellicle membrane,
an adhesive for an original plate, and
a pellicle frame; and
wherein an outgas amount is 2.9 μg or less when measured under the following Condition 4:
Condition 4:
a pellicle is heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the pellicle is measured under a heating condition of 280 °C for ten minutes,
wherein the total amount of the outgas is obtained by n-decane conversion.

8. The pellicle according to claim 6, wherein the adhesive for an original plate is a styrene butadiene-based adhesive.

9. The pellicle casing according to claim 7, wherein the adhesive for an original plate is a styrene butadiene-based adhesive.

10. The clip for a pellicle storage container according to claim 2, comprising at least one type of resin selected from the group consisting of a urethane resin, a polyethylene resin, a polyethylene terephthalate resin, a polyvinyl chloride resin, a polyamide resin, a polycarbonate resin, an acrylic resin, a methacrylic resin, and a phenol resin.

11. A pellicle casing comprising:
a pellicle;
a pellicle storage container that stores the pellicle;
the clip for a pellicle storage container according to claim 2, which fixes the pellicle storage container; and
a pellicle packaging body that packages the pellicle storage container.

12. The pellicle casing according to claim 11, wherein the clip for a pellicle storage container that fixes the pellicle storage container has a total amount of 1500 μg or less of an outgas amount of an organic substance gas having 20 or less carbon atoms measured under the following Condition 3:
Condition 3:
a clip used in a pellicle casing is placed as a sample in a container, and an extract is obtained by Soxhlet extraction using 200 ml of hexane as an extraction solvent in a water bath at 80 °C for six hours, and the obtained extract is analyzed using gas chromatography, wherein, in the gas chromatography, a flame ionization detector is used as a detector, an amount of a component having 20 or less carbon atoms is detected, and a total amount of the detected component having 20 or less carbon atoms is defined as the outgas amount.

13. A pellicle casing comprising:
a pellicle storage container that stores a pellicle,
the clip for a pellicle storage container according to claim 2, which fixes the pellicle storage container, and
a pellicle packaging body that packages the pellicle storage container,
wherein the pellicle, which is placed within the pellicle storage container, comprises:
a pellicle membrane,
an adhesive for an original plate, and
a pellicle frame; and
wherein an outgas amount is 2.9 μg or less when measured under the following Condition 4:
Condition 4:
a pellicle is heated at 50 °C for four hours, and a generated outgas is adsorbed onto 150 mg of an adsorbent material, and thereafter, 150 mg of the adsorbent material is set in a gas chromatograph mass spectrometer, and a total amount of an outgas of a volatile organic component generated from the pellicle is measured under a heating condition of 280 °C for ten minutes,
wherein the total amount of the outgas is obtained by n-decane conversion.

14. The pellicle casing according to claim 13, wherein the adhesive for an original plate is a styrene butadiene-based adhesive.
